(19) United States
(12) Patent Application Publication
(10) Pub. No.: US 2023/0313653 A1
(43) Pub. Date: Oct. 5, 2023

(54) EFFECTIVE PERFORATION CLUSTER DETERMINATION FROM HYDRAULIC FRACTURING DATA

(71) Applicant: Schlumberger Technology Corporation, Sugar Land, TX (US)

(72) Inventors: Juan David ESTRADA BENAVIDES, Bogota (US); Dylan ALMEIDA, Sugar Land, TX (US); Andrew BONNELL, Sugar Land, TX (US); Jared BRUNS, Houston, TX (US); Ziyao LI, Houston, TX (US)

(21) Appl. No.: 18/044,395

(22) PCT Filed: Sep. 8, 2021
(86) PCT No.: PCT/US2021/071385

§ 371 Date: Mar. 8, 2023

Related U.S. Application Data
(60) Provisional application No. 63/075,337, filed on Sep. 8, 2020.

(51) Int. Cl. E21B 43/26; E21B 49/00

(52) U.S. Cl. CPC E21B 43/2607; E21B 49/00; E21B 2200/22

(57) ABSTRACT

Systems and methods presented herein relate to systems and methods for determining a number of effective perforation clusters created during hydraulic fracturing operations performed using wellsite equipment of a wellsite system based on surface data collected in substantially real-time during the hydraulic fracturing operations using an autoencoder/convolutional neural network architecture. In certain embodiments, the wellsite equipment of the wellsite system may be controlled in substantially real-time based on the determined number of effective perforation clusters insofar as the autoencoder/convolutional neural network architecture facilitates such real-time responsiveness.

### CROSS-REFERENCE TO RELATED APPLICATION

This application claims priority to and the benefit of U.S. Provisional Patent Application Ser. No. 63/075,337, entitled “Effective Perforation Cluster Determination from Hydraulic Fracturing Data,” filed Sep. 8, 2020, which is hereby incorporated by reference in its entirety for all purposes.

### BACKGROUND

The present disclosure generally relates to systems and methods for determining a number of effective perforation clusters created during hydraulic fracturing operations performed using wellsite equipment of a wellsite system based on surface data collected in substantially real-time during the hydraulic fracturing operations using an autoencoder/convolutional neural network architecture.

This section is intended to introduce the reader to various aspects of art that may be related to various aspects of the present techniques, which are described and/or claimed below. This discussion is believed to be helpful in providing the reader with background information to facilitate a better understanding of the various aspects of the present disclosure. Accordingly, it should be understood that these statements are to be read in this light, and not as an admission of any kind.

Hydraulic fracturing may be utilized in various types of wells, which may include one or more vertical portions, one or more lateral portions, etc. A horizontal well with multiple fracturing stages, with each stage containing multiple perforation clusters to initiate multiple fractures, has become one of the most common choices of well completion in developing unconventional oil and gas resources (e.g., unconventional reservoirs). However, downhole diagnostic measurements using fiber optic technology or production logging often indicate that not each perforation cluster is effectively stimulated, which can negatively impact well production. There are several possible mechanisms that can lead to uneven stimulation among multiple perforations, including lateral heterogeneity of the reservoir properties, especially the in-situ stress, poor limited-entry perforation design to provide sufficient divertive perforation friction to overcome the stress differences, perforation erosion by proppant that reduces the perforation friction, and the mechanical interference between adjacent fractures (e.g., the so-called stress shadow effect).

Historically, understanding of the subterranean conditions during stimulation treatments has been reserved for relatively invasive and expensive tools such as micro-seismic, downhole cameras, radio-active tracers, and fiber optics (e.g., distributed acoustic sensing (DAS), distributed temperature sensing (DTS), and so forth) that increase completion cost and reduce completion efficiency. Moreover, the results of these sophisticated and expensive measurements require either further processing or expert interpretation to be meaningful. As such, rarely do these technologies allow actionable, real-time changes during hydraulic fracturing treatments to increase stimulation efficiency, and it is highly unlikely that observations from these wells are successfully expanded to future developments within the same reservoir. Lastly, operators must often wait for at least six months of production data to assess whether the changes implemented from these expensive completions were successful or not. At the same time, data collected on the surface has been largely disregarded to extract details concerning the downhole environment, as such data has been deemed insufficient. Nonetheless, ubiquitous sets of surface data and treating parameters have been collected during the last 70 years of hydraulic fracturing experience worldwide.

### SUMMARY

A summary of certain embodiments described herein is set forth below. It should be understood that these aspects are presented merely to provide the reader with a brief summary of these certain embodiments and that these aspects are not intended to limit the scope of this disclosure.

Certain embodiments of the present disclosure include a computer-implemented method that includes receiving, via a control center, a plurality of inputs relating to operational parameters of wellsite equipment of a wellsite system during hydraulic fracturing operations performed for the wellsite system. The computer-implemented method also includes converting, via the control center, the plurality of inputs into a plurality of outputs relating to operational parameters of the wellsite equipment. The computer-implemented method further includes generating, via the control center, time series of the plurality of outputs. In addition, the computer-implemented method includes using, via the control center, a convolutional neural network to automatically analyze the time series of the plurality of outputs to determine a number of effective perforation clusters created during the hydraulic fracturing operations. The computer-implemented method also includes controlling, via the control center, operational parameters of the wellsite equipment based at least in part on the determined number of effective perforation clusters.

In addition, certain embodiments of the present disclosure include a system that includes a control center configured to control operational parameters of wellsite equipment of a wellsite system during hydraulic fracturing operations performed for the wellsite system. The control center is configured to control the operational parameters of the wellsite equipment based at least in part on a number of effective perforation clusters created during the hydraulic fracturing operations. The control center includes an autoencoder configured to receive a plurality of inputs relating to operational parameters of the wellsite equipment, and to compress the plurality of inputs into a plurality of outputs. A number of the plurality of outputs is less than a number of the plurality of inputs. The control center also includes a convolutional neural network configured to automatically analyze time series of the plurality of outputs to determine the number of effective perforation clusters.

In addition, certain embodiments of the present disclosure include a tangible, non-transitory machine-readable medium that includes processor-executable instructions that, when executed by at least one processor, cause the at least one processor to receive a plurality of inputs relating to operational parameters of wellsite equipment of a wellsite system during hydraulic fracturing operations performed for the wellsite system. The processor-executable instructions, when executed by the at least one processor, also cause the at least one processor to use an autoencoder to compress the plurality of inputs into a plurality of outputs. A number of the plurality of outputs is less than a number of the plurality of inputs. The processor-executable instructions, when executed by the at least one processor, further cause the at least one processor to generate time series of the plurality of outputs. In addition, the processor-executable instructions, when executed by the at least one processor, cause the at least one processor to use a convolutional neural network to automatically analyze the time series of the plurality of outputs to determine a number of effective perforation clusters created during the hydraulic fracturing operations. The processor-executable instructions, when executed by the at least one processor, also cause the at least one processor to control operational parameters of the wellsite equipment based at least in part on the determined number of effective perforation clusters.

Various refinements of the features noted above may be undertaken in relation to various aspects of the present disclosure. Further features may also be incorporated in these various aspects as well. These refinements and additional features may exist individually or in any combination. For instance, various features discussed below in relation to one or more of the illustrated embodiments may be incorporated into any of the above-described aspects of the present disclosure alone or in any combination. The brief summary presented above is intended to familiarize the reader with certain aspects and contexts of embodiments of the present disclosure without limitation to the claimed subject matter.

### BRIEF DESCRIPTION OF THE DRAWINGS

Various aspects of this disclosure may be better understood upon reading the following detailed description and upon reference to the drawings, in which:

FIG. 1 is a schematic view of at least a portion of a wellsite system, in accordance with embodiments of the present disclosure;

FIG. 2 illustrates a partially horizontal wellbore from which a hydraulic fracturing tool has created a plurality of perforation clusters, in accordance with embodiments of the present disclosure;

FIG. 3 is a block diagram of a computing system configured to control operation of the wellsite system of FIG. 1 and/or to determine a number of effective perforation clusters, in accordance with embodiments of the present disclosure;

FIG. 4 is a flow diagram of a method for determining and using a number of effective perforation clusters, in accordance with embodiments of the present disclosure;

FIG. 5 illustrates an example autoencoder and a convolutional neural network for use in determining a number of effective perforation clusters, in accordance with embodiments of the present disclosure; and

FIG. 6 illustrates an example convolutional neural network for use in determining a number of effective perforation clusters, in accordance with embodiments of the present disclosure.

### DETAILED DESCRIPTION

One or more specific embodiments of the present disclosure will be described below. These described embodiments are only examples of the presently disclosed techniques. Additionally, in an effort to provide a concise description of these embodiments, all features of an actual implementation may not be described in the specification. It should be appreciated that in the development of any such actual implementation, as in any engineering or design project, numerous implementation-specific decisions must be made to achieve the developers' specific goals, such as compliance with system-related and business-related constraints, which may vary from one implementation to another. Moreover, it should be appreciated that such a development effort might be complex and time consuming, but would nevertheless be a routine undertaking of design, fabrication, and manufacture for those of ordinary skill having the benefit of this disclosure.

When introducing elements of various embodiments of the present disclosure, the articles “a,” “an,” and “the” are intended to mean that there are one or more of the elements. The terms “comprising,” “including,” and “having” are intended to be inclusive and mean that there may be additional elements other than the listed elements. Additionally, it should be understood that references to “one embodiment” or “an embodiment” of the present disclosure are not intended to be interpreted as excluding the existence of additional embodiments that also incorporate the recited features.

As used herein, the terms “connect,” “connection,” “connected,” “in connection with,” and “connecting” are used to mean “in direct connection with” or “in connection with via one or more elements”; and the term “set” is used to mean “one element” or “more than one element.” Further, the terms “couple,” “coupling,” “coupled,” “coupled together,” and “coupled with” are used to mean “directly coupled together” or “coupled together via one or more elements.” As used herein, the terms “up” and “down,” “uphole” and “downhole”, “upper” and “lower,” “top” and “bottom,” and other like terms indicating relative positions to a given point or element are utilized to more clearly describe some elements. Commonly, these terms relate to a reference point as the surface from which drilling operations are initiated as being the top (e.g., uphole or upper) point and the total depth along the drilling axis being the lowest (e.g., downhole or lower) point, whether the well (e.g., wellbore, borehole) is vertical, horizontal or slanted relative to the surface.

As used herein, a fracture shall be understood as one or more cracks or surfaces of breakage within rock. Certain fractures may also be referred to as natural fractures to distinguish them from fractures induced as part of a reservoir stimulation. Fractures can also be grouped into fracture clusters (or “perforation clusters”) where the fractures of a given fracture cluster (perforation cluster) connect to the wellbore through a single perforated zone. As used herein, the term “fracturing” or “hydraulic fracturing” refers to the process and methods of breaking down a geological formation and creating a fracture (i.e., the rock formation around a wellbore) by pumping fluid at relatively high pressures (e.g., pressure above the determined closure pressure of the formation) in order to increase production rates from a hydrocarbon reservoir.

In addition, as used herein, the terms “real time”, “real-time”, “substantially real time”, “substantially real-time” may be used interchangeably and are intended to describe operations (e.g., computing operations) that are performed without any human-perceivable interruption between operations. For example, as used herein, data relating to the systems described herein may be collected, transmitted, and/or used in control computations in “substantially real time” such that data readings, data transfers, data processing steps, and/or control steps occur once every second, once every 0.1 second, once every 0.01 second, or even more frequent, during operations of the systems (e.g., while the systems are operating). In addition, as used herein, the terms “automatic” and “automated” are intended to describe operations that are performed are caused to be performed, for example, by a process control system (i.e., solely by the process control system, without human intervention).

As described in greater detail herein, through deep learning, robust data sources, and customer provided validation, the embodiments of the present disclosure is believed to provide the industry's first surface-based/non-invasive algorithms to determine stimulation effectiveness. The algorithms described herein determine the number of effective fractures during each stage on a horizontal well completion in real-time, thereby enabling better decision making and providing a new level of understanding about completion and reservoir performance without incurring expensive investments on a routine basis.

In particular, the embodiments described herein describe the development of a feature extractor with a convolutional neural network to determine a number of effective clusters from hydraulic fracturing treatment data in substantially real-time (or after a treatment has been completed). The embodiments described herein also describe the optimization of hydraulic fracturing surface rate to increase the number of effective clusters during a treatment. Historical time series inputs are used to train the model to determine cluster effectiveness using a probability distribution, as described in greater detail herein.

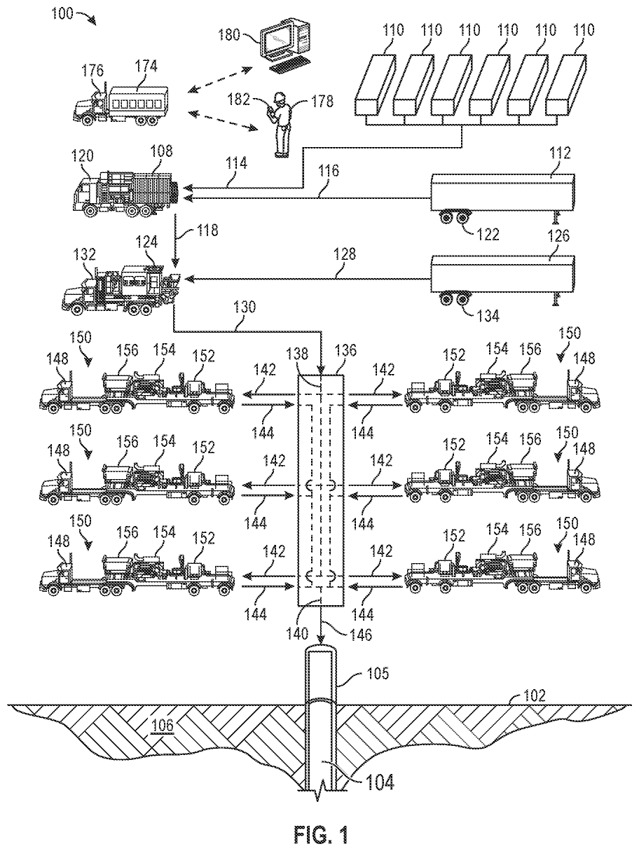

FIG. 1 is a schematic view of at least a portion of a wellsite system 100 that may utilize the embodiments described herein. In particular, FIG. 1 illustrates a wellsite 102, a wellbore 104 extending from the terrain surface of the wellsite 102, a partial sectional view of a subterranean formation 106 penetrated by the wellbore 104, and a wellhead 105, as well as various pieces of equipment or components located at the wellsite 102. In certain embodiments, the wellsite system 100 may be operable to transfer various materials and additives from corresponding sources to a destination location for blending or mixing and eventual injection into the wellbore 104 during fracturing operations.

In certain embodiments, the wellsite system 100 may include a mixing unit 108 (referred to hereinafter as a “first mixer”) fluidly connected with one or more tanks 110 and a first container 112. In certain embodiments, the first container 112 may contain a first material and the tanks 110 may contain a liquid. In certain embodiments, the first material may be or comprise a hydratable material or gelling agent, such as guar, polymers, synthetic polymers, galactomannan, polysaccharides, cellulose, and/or clay, among other examples, whereas the liquid may be or comprise an aqueous fluid, such as water or an aqueous solution comprising water, among other examples. In certain embodiments, the first mixer 108 may be operable to receive the first material and the liquid, via two or more conduits or other material transfer means (hereafter simply “conduits”) 114, 116, and mix or otherwise combine the first material and the liquid to form a base fluid, which may be or comprise what is referred to as a gel. In certain embodiments, the first mixer 108 may then discharge the base fluid via one or more fluid conduits 118.

In certain embodiments, the wellsite system 100 may also include a second mixer 124 fluidly connected with the first mixer 108 and a second container 126. In certain embodiments, the second container 126 may contain a second material that may be substantially different than the first material. For example, in certain embodiments, the second material may be or comprise a proppant material, such as sand, sand-like particles, silica, quartz, and/or propping agents, among other examples. In certain embodiments, the second mixer 124 may be operable to receive the base fluid from the first mixer 108 via the one or more fluid conduits 118, and the second material from the second container 126 via one or more fluid conduits 128, and mix or otherwise combine the base fluid and the second material to form a slurry, which may be or comprise what is referred to as a hydraulic fracturing fluid. In certain embodiments, the second mixer 124 may then discharge the slurry via one or more fluid conduits 130.

In certain embodiments, the slurry may be distributed from the second mixer 124 to a common manifold 136 via the one or more fluid conduits 130. In certain embodiments, the common manifold 136 may include various valves and diverters, as well as a suction line 138 and a discharge line 140, such as may be collectively operable to direct the flow of the slurry from the second mixer 124 in a selected or predetermined manner. In certain embodiments, the common manifold 136 may distribute the slurry to a fleet of pump units 150. Although the fleet is illustrated in FIG. 1 as including six pump units 150, the fleet may instead include other quantities of pump units 150 within the scope of the present disclosure.

In certain embodiments, each pump unit 150 may include at least one pump 152, at least one prime mover 154, and perhaps at least one heat exchanger 156. In certain embodiments, each pump unit 150 may receive the slurry from the suction line 138 of the common manifold 136, via one or more fluid conduits 142, and discharge the slurry under pressure to the discharge line 140 of the common manifold 136, via one or more fluid conduits 144. In certain embodiments, the slurry may then be discharged from the common manifold 136 into the wellbore 104 via one or more fluid conduits 146, the wellhead 105, and perhaps various additional valves, conduits, and/or other hydraulic circuitry fluidly connected between the common manifold 136 and the wellbore 104.

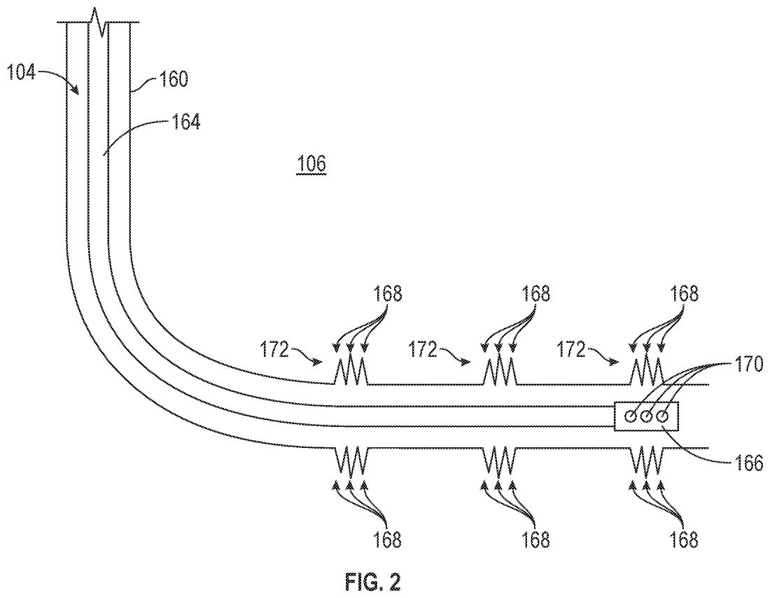

In particular, as illustrated in FIG. 2, in certain embodiments, the slurry (i.e., hydraulic fracturing fluid) may be pumped downhole into the wellbore 104 (e.g., formed by a casing 160 extending through the subterranean formation 106) via a tubing string 164 (e.g., coiled tubing, in certain embodiments) having a hydraulic fracturing tool 166 disposed near a bottom of the tubing string 164. In certain embodiments, the slurry is pumped down through the tubing string 164 and dispersed into the subterranean formation 106 via a plurality of perforations 168 formed by one or more perforating guns 170 of the hydraulic fracturing tool 166. As illustrated in FIG. 2, the perforating guns 170 of the hydraulic fracturing tool 166 may form a plurality of perforations 168 at each of a plurality of locations (e.g., stages) along the wellbore 104. Each grouping of perforations 168 may be referred to herein as a perforation cluster 172. As described in greater detail herein, in certain embodiments, a number of effective perforation clusters 172 may be determined, for example, using a convolutional neural network acting on a subset of operational parameters in substantially real-time to enable real-time control of the effectiveness of the perforation clusters 172 (e.g., during performance of fracturing operations using the hydraulic fracturing tool 166).

Returning now to FIG. 1, in certain embodiments, the wellsite system 100 may also include a control center 174, which may be or comprise a controller, such as may be operable to (e.g., automatically, in certain embodiments) provide control signals to one or more portions of the wellsite system 100 and/or may be operable to determine a number of effective perforation clusters created during fracturing operations performed by the wellsite system 100, as described in greater detail herein. For example, in certain embodiments, the control center 174 may be operable to monitor and control one or more portions of the mixers 108, 124, the pump units 150, the common manifold 136, and various other pumps, conveyers, and/or other wellsite equipment (not shown) disposed along the conduits 114, 116, 118, 128, 130, such as may be operable to move, mix, separate, or measure the fluids, materials, and/or slurries described above and inject such fluids, materials, and/or slurries into the wellbore 104. Communication between the control center 174 and the various portions of the wellsite system 100 may be via wired and/or wireless communication means. However, for clarity and ease of understanding, such communication means are not depicted in FIG. 1, and a person having ordinary skill in the art will appreciate that such communication means are within the scope of the present disclosure.

As described in greater detail herein, an autoencoder and convolutional neural network enable the control center 174 to automatically compress and analyze inputs relating to operational parameters of the wellsite equipment illustrated in FIG. 1 from sensors associated with the wellsite equipment to determine a number of effective perforation clusters (and, indeed, in certain embodiments, automatically control operational parameters of the wellsite equipment based in the determined number of effective perforation clusters) in an unsupervised manner in substantially real time, without the need for human intervention. In particular, it will be appreciated that the computational efficiency of the autoencoder and convolutional neural network described herein would not be possible for a human to perform mentally, and certainly would not be possible for a human to perform mentally in substantially real-time during operation of the wellsite equipment to effectively control operational parameters of the wellsite equipment based a determined number of effective perforation clusters.

As illustrated in FIG. 1, in certain embodiments, one or more of the containers 112, 126, the mixers 108, 124, the pump units 150, and the control center 174 may each be disposed on corresponding trucks, trailers, and/or other mobile carriers 120, 132, 148, 176, such as may permit their transportation to the wellsite surface 102. However, in other embodiments, one or more of the containers 112, 126, the mixers 108, 124, the pump units 150, and the control center 174 may each be skidded or otherwise stationary, and/or may be temporarily or permanently installed at the wellsite 102. In addition, although illustrated in FIG. 1 as being a control center 174 located at or near the wellsite system 100, in other embodiments, the control center 174 may be located remotely from the wellsite system 100, for example, at an offsite location.

In certain embodiments, a field engineer, equipment operator, or field operator 178 (collectively referred to hereinafter as a “wellsite operator”) may operate one or more components, portions, or systems of the wellsite equipment and/or perform maintenance or repair on the wellsite equipment. For example, in certain embodiments, the wellsite operator 178 may assemble the wellsite system 100, operate the wellsite equipment to perform the fracturing operations, check equipment operating parameters, and repair or replace malfunctioning or inoperable wellsite equipment, among other operational, maintenance, and repair tasks, collectively referred to hereinafter as wellsite operations. In certain embodiments, the wellsite operator 178 may perform wellsite operations by himself or with other wellsite operators. In certain embodiments, during wellsite operations, the wellsite operator 178 may communicate instructions to the other operators via a computer 180 and/or a communication device 182. In certain embodiments, the wellsite operator 178 may also (e.g., automatically, in certain embodiments) communicate control signals or other information to the control center 174 via the computer 180 or the communication device 182 during and/or before the wellsite operations. In certain embodiments, the wellsite operator 178 may also control one or more components, portions, or systems of the wellsite system 100 from the control center 174 or via the computer 180 or the communication device 182.

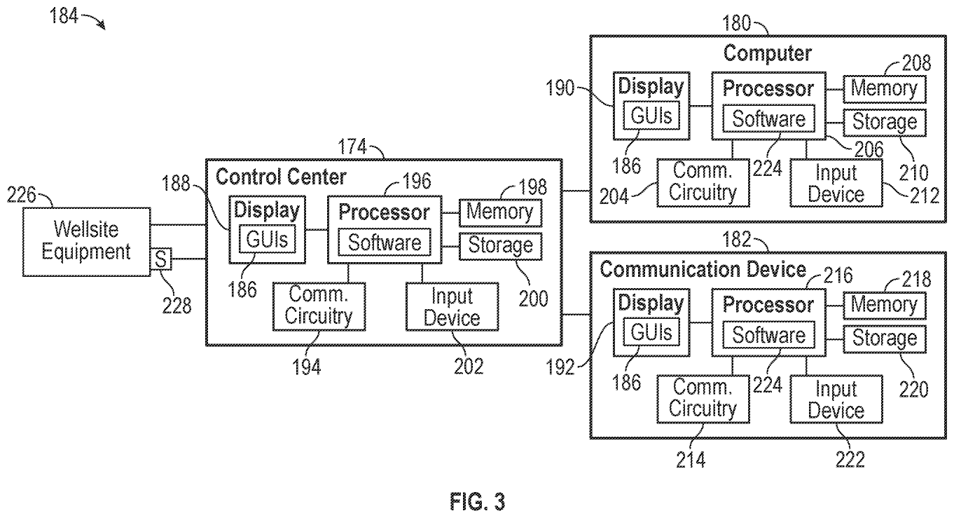

FIG. 3 is a block diagram of a computing system 184 configured to control operation of the wellsite system 100 of FIG. 1 and/or to determine a number of effective perforation clusters 172, as described in greater detail herein. For example, in certain embodiments, the computing system 184 may include the control center 174 (or some other control system), which may be configured to provide graphical user interfaces 186 to a display 188 of the control center 174 itself, a display 190 of one or more computers 180, a display 192 of one or more communication devices 182, or some combination thereof, to facilitate interaction of a wellsite operator 178 with wellsite equipment 226 of the wellsite system 100 of FIG. 1 and/or to monitor a number of effective perforation clusters 172 during hydraulic fracturing operations, for example, to enable real-time control of the effectiveness of the perforation clusters 172.

The control center 174, in certain embodiments, may be or include one or more computers that may be connected through a real-time communication network, such as the Internet. In certain embodiments, analysis or processing operations may be distributed over the computers that make up the control center 174. In certain embodiments, the control center 174 may receive information from various sources, such as via inputs received from the computers 180, from the communication devices 182, or from other computing devices.

As illustrated, in certain embodiments, the control center 174 may include communication circuitry 194, at least one processor 196, at least one memory medium 198, at least one storage medium 200, at least one input device 202, the display 188, and any of a variety of other components that enable the control center 174 to carry out the techniques described herein. The communication circuitry 194 may include wireless or wired communication circuitry, which may facilitate communication with the wellsite equipment 226 of the wellsite system 100 of FIG. 1, the computers 180, the communication devices 182, and other devices or systems.

The at least one processor 196 may be any suitable type of computer processor or microprocessor capable of executing computer-executable code. The at least one processor 196 may also include multiple processors that may perform the operations described herein. The at least one memory medium 198 and the at least one storage medium 200 may be any suitable articles of manufacture that can serve as media to store processor-executable code, data, or the like. These articles of manufacture may represent computer-readable media (e.g., any suitable form of memory or storage) that may store the processor-executable code used by the at least one processor 196 to perform the presently disclosed techniques. The at least one memory medium 198 and/or the at least one storage medium 200 may also be used to store the data, various other software applications, and the like. The at least one memory medium 198 and the at least one storage medium 200 may represent non-transitory computer-readable media (e.g., any suitable form of memory or storage) that may store the processor-executable code used by the at least one processor 196 to perform various techniques described herein. It should be noted that non-transitory merely indicates that the media is tangible and not a signal.

In certain embodiments, the at least one processor 196 of the control center 174 may communicate with the wellsite equipment 226 of the wellsite system 100 of FIG. 1, the computers 180, the communication devices 182, and other devices or systems, to facilitate the techniques described herein. Specifically, in certain embodiments, the at least one processor 196 of the control center 174 may execute the processor-executable code stored in the at least one memory medium 198 and/or the at least one storage medium 200 of the control center 174 to provide the graphical user interfaces 186 configured to facilitate interaction of a wellsite operator 178 with wellsite equipment 226 of the wellsite system 100 of FIG. 1 and/or to monitor a number of effective perforation clusters 172 during hydraulic fracturing operations, for example, to enable real-time control of the effectiveness of the perforation clusters 172, as described in greater detail herein. In addition, in certain embodiments, the at least one input device 202 of the control center 174 may be configured to receive input commands (e.g., from a wellsite operator 178), which may be used by the control center 174 to facilitate the interaction of the wellsite operator 178 with wellsite equipment 226 of the wellsite system 100 of FIG. 1 and/or to monitor a number of effective perforation clusters 172 during hydraulic fracturing operations, for example, to enable real-time control of the effectiveness of the perforation clusters 172, as described in greater detail herein. In certain embodiments, the at least one input device 202 may include a mouse, touchpad, touchscreen, keyboard and so forth.

It should also be noted that the components described above with regard to the control center 174 are exemplary components, and the control center 174 may include additional or fewer components in certain embodiments. Additionally, it should be noted that the computers 180 and the communication devices 182 may also include similar components as described as part of the control center 174 (e.g., respective communication devices, processors, memory media, storage media, displays, and input devices) to facilitate the disclosed operation of the computing system 184.

For example, as illustrated in FIG. 3, in certain embodiments, the computers 180 may include communication circuitry 204, at least one processor 206, at least one memory medium 208, at least one storage medium 210, at least one input device 212, and the display 190 described herein. The communication circuitry 204 may include wireless or wired communication circuitry, which may facilitate communication with the communication circuitry 194 of the control center 174, for example.

The at least one processor 206 may be any suitable type of computer processor or microprocessor capable of executing computer-executable code. The at least one processor 206 may also include multiple processors, in certain embodiments. The at least one memory medium 208 and the at least one storage medium 210 may be any suitable articles of manufacture that can serve as media to store processor-executable code, data, or the like. These articles of manufacture may represent computer-readable media (e.g., any suitable form of memory or storage) that may store the processor-executable code used by the at least one processor 206. The at least one memory medium 208 and/or the at least one storage medium 210 may also be used to store the data, various other software applications, and the like. The at least one memory medium 208 and the at least one storage medium 210 may represent non-transitory computer-readable media (e.g., any suitable form of memory or storage) that may store the processor-executable code used by the at least one processor 206 to perform various techniques described herein.

In certain embodiments, the computers 180 may receive signals relating to the graphical user interfaces 186 from the control center 174, for example, via communication of the communication circuitry 194, 204 of the control center 174 and the computers 180, respectively. The at least one processor 206 of the computers 180 may execute processor-executable code stored in the at least one memory medium 208 and/or the at least one storage medium 210 of the computers 180 to cause the graphical user interfaces 186 to be displayed via the display 190 of the computers 180 in accordance with the signals received from the control center 174, as described in greater detail herein. In addition, in certain embodiments, the at least one input device 212 of the computers 180 may be configured to receive input commands (e.g., from a wellsite operator 178), which may be used by the control center 174 to facilitate interaction of a wellsite operator 178 with wellsite equipment 226 of the wellsite system 100 of FIG. 1 and/or to monitor a number of effective perforation clusters 172 during hydraulic fracturing operations, for example, to enable real-time control of the effectiveness of the perforation clusters 172, as described in greater detail herein. In certain embodiments, the at least one input device 212 may include a mouse, touchpad, touchscreen, keyboard and so forth.

Similarly, as also illustrated in FIG. 3, in certain embodiments, the communication devices 182 may also include communication circuitry 214, at least one processor 216, at least one memory medium 218, at least one storage medium 220, at least one input device 222, and the display 192 described herein. In certain embodiments, the communication devices 182 may be dedicated client devices, laptops, tablet computers, cellular telephones, and so forth. The communication circuitry 214 may include wireless or wired communication circuitry, which may facilitate communication with the communication circuitry 194 of the control center 174, for example.

The at least one processor 216 may be any suitable type of computer processor or microprocessor capable of executing computer-executable code. The at least one processor 216 may also include multiple processors, in certain embodiments. The at least one memory medium 218 and the at least one storage medium 220 may be any suitable articles of manufacture that can serve as media to store processor-executable code, data, or the like. These articles of manufacture may represent computer-readable media (e.g., any suitable form of memory or storage) that may store the processor-executable code used by the at least one processor 216. The at least one memory medium 218 and/or the at least one storage medium 220 may also be used to store the data, various other software applications, and the like. The at least one memory medium 218 and the at least one storage medium 220 may represent non-transitory computer-readable media (e.g., any suitable form of memory or storage) that may store the processor-executable code used by the at least one processor 216 to perform various techniques described herein.

Similarly, in certain embodiments, the communication devices 182 may also receive signals relating to the graphical user interfaces 186 from the control center 174, for example, via communication of the communication circuitry 194, 214 of the control center 174 and the communication devices 182, respectively. The at least one processor 216 of the communication devices 182 may execute processor-executable code stored in the at least one memory medium 218 and/or the at least one storage medium 220 of the communication devices 182 to cause the graphical user interfaces 186 to be displayed via the display 192 of the communication devices 182 in accordance with the signals received from the control center 174, as described in greater detail herein. In addition, in certain embodiments, the at least one input device 222 of the communication devices 182 may be configured to receive input commands (e.g., from a wellsite operator 178), which may be used by the control center 174 to facilitate interaction of a wellsite operator 178 with wellsite equipment 226 of the wellsite system 100 of FIG. 1 and/or to monitor a number of effective perforation clusters 172 during hydraulic fracturing operations, for example, to enable real-time control of the effectiveness of the perforation clusters 172, as described in greater detail herein. In certain embodiments, the at least one input device 222 may include a mouse, touchpad, touchscreen, keyboard and so forth.

In addition, the graphical user interfaces 186 may be presented as software 224 running on the various devices described herein, wherein the software 224 facilitates control of the wellsite equipment 226 of the wellsite system 100 of FIG. 1 via the graphical user interfaces 186 and/or monitoring of a number of effective perforation clusters 172 during hydraulic fracturing operations, for example, to enable real-time control of the effectiveness of the perforation clusters 172, as described in greater detail herein.

In addition, as illustrated in FIG. 3, wellsite equipment 226 may be monitored by the control center 174 using sensors 228 associated with the wellsite equipment 226, as described in greater detail herein. The wellsite equipment 226 illustrated in FIG. 3 is intended to encompass any and all of the equipment illustrated in FIG. 1, as well as other wellsite equipment 226 of the wellsite system 100 of FIG. 1. As described in greater detail herein, the control center 174 may receive inputs relating to operational parameters of the wellsite equipment 226 of the wellsite system 100 of FIG. 1 from the sensors 228, and may use these received inputs to facilitate control of the wellsite equipment 226 and/or monitoring of a number of effective perforation clusters 172 during hydraulic fracturing operations, for example, to enable real-time control of the effectiveness of the perforation clusters 172.

In general, the data relating to the operational parameters of the wellsite equipment 226 detected by the sensors 228 may be referred to as “surface data” insofar as the data collection is taking place at the surface of the wellsite 102 during hydraulic fracturing operations, as opposed to “downhole data”, which is collected via downhole tools disposed in the wellbore 104 during the hydraulic fracturing operations. It is believed that determining the number of effective perforation clusters 172 using surface data, as opposed to downhole data, facilitates even faster active (e.g., real-time) control of the effectiveness of the perforation clusters 172, as described in greater detail herein, insofar as the control center 174 generally receives actionable surface data faster than downhole data, due at least in part to the relative proximity of the surface sensors 228 to the control center 174 (as compared to sensors of downhole tools).

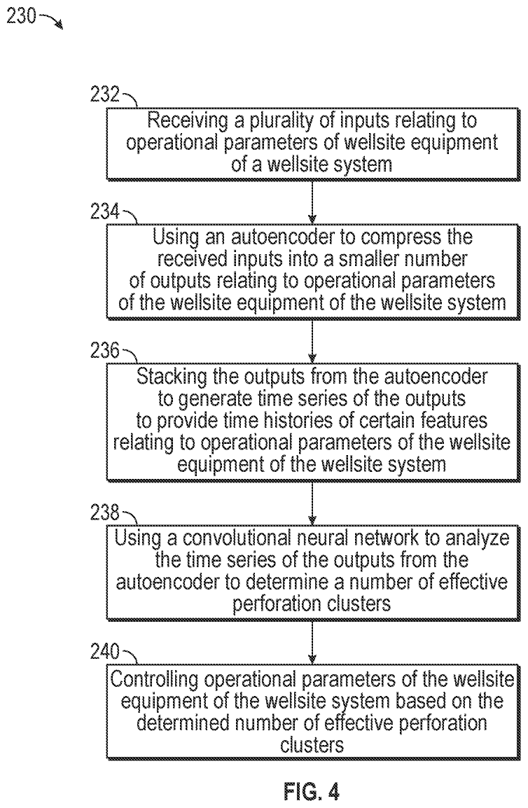

FIG. 4 is a flow diagram of a method 230 for determining and using a number of effective perforation clusters 172, which may be performed by the control center 174, as described herein. As illustrated, in certain embodiments, the method 230 includes receiving a plurality of inputs relating to operational parameters of wellsite equipment 226 of the wellsite system 100 of FIG. 1 (block 232). In addition, in certain embodiments, the method 230 includes using an autoencoder to automatically compress the received inputs into a smaller number of outputs relating to operational parameters of the wellsite equipment 226 of the wellsite system 100 of FIG. 1 (block 234). In addition, in certain embodiments, the method 230 includes automatically stacking the outputs to generate time series (e.g., having 120 timesteps, in certain embodiments) of the outputs to provide time histories of certain features relating to operational parameters of the wellsite equipment 226 of the wellsite system 100 of FIG. 1 (block 236). In addition, in certain embodiments, the method 230 includes using a convolutional neural network to automatically analyze the time series of the outputs to determine a number of effective perforation clusters 172 (block 238). In addition, in certain embodiments, the method 230 includes (e.g., automatically, in certain embodiments) controlling operational parameters of the wellsite equipment 226 of the wellsite system 100 of FIG. 1 based at least in part on the determined number of effective perforation clusters 172 (block 240).

The method 230 illustrated in FIG. 4 includes determining a number of effective peroration clusters 172 in substantially real-time during a stimulation treatment based on surface hydraulic fracturing datasets collected in substantially real-time, as opposed to determining the efficiency of a plurality of perforation clusters 172 (e.g., whereby, for example, flow rate only goes through one of three perforation clusters 172). As described herein, the term “effective perforation cluster” is defined as a perforation cluster 172 that receives an injection rate of slurry fluid within a predetermined range of planned flow rate for that particular perforation cluster 172, for example, as determined from the completion design. In contrast, the term “ineffective perforation cluster” is defined as a perforation cluster 172 that receives an injection rate of slurry fluid above or below the predetermined range of planned flow rate for that particular perforation cluster 172, for example, as determined from the completion design. Each of the method steps illustrated in FIG. 4 will be described in further detail below.

As illustrated in FIG. 4, the method 230 for determining and using a number of effective perforation clusters 172 includes the control center 174 receiving a plurality of inputs relating to operational parameters of wellsite equipment 226 of the wellsite system 100 of FIG. 1 (block 232). For example, in certain embodiments, the control center 174 may receive the inputs relating to the operational parameters of the wellsite equipment 226 from sensors 228 associated with the wellsite equipment 226 in substantially real-time. In certain embodiments, the inputs received from the sensors 228 may include seven inputs—a clean fluid rate (e.g., a flow rate of clean fluid from the tanks 110 to the first mixer 108 via conduits 114, as illustrated in FIG. 1), a total amount of fluid used (e.g., a total amount of fluid from the first mixer 108 to the second mixer 124 via conduits 118, as illustrated in FIG. 1), a total amount of proppant used (e.g., a total amount of proppant from the second container 126 to the second mixer 124 via conduits 128, as illustrated in FIG. 1), a concentration of proppant used (e.g., a concentration of the proppant from the second container 126 to the second mixer 124 via conduits 128, as illustrated in FIG. 1), a total amount of slurry (e.g., a total amount of slurry pumped through the pumps 152, as illustrated in FIG. 1), a slurry rate (e.g., a flow rate of slurry pumped through the pumps 152, as illustrated in FIG. 1), and a treatment pressure (e.g., reservoir response pressure during hydraulic fracturing treatment). These seven inputs were chosen based on a physical representation of hydraulic fracture propagation from available surface monitoring datasets collected over time. In addition, it has been observed that these seven inputs are quite often available across various service industries. However, these seven inputs are not intended to be limiting and, in other embodiments, other inputs relating to other operational parameters may be used to capture pressure evolution at the bottom of the well and how these magnitudes drive overall flow distribution across the available perforation clusters 172.

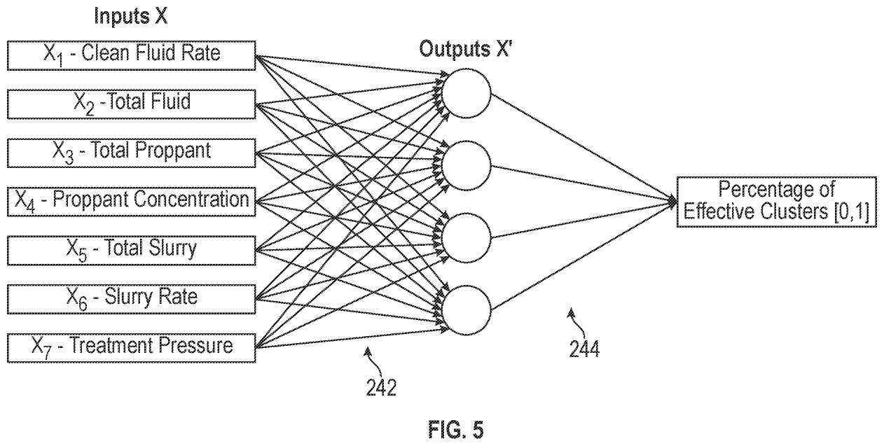

In addition, as illustrated in FIG. 4, the method 230 for determining and using a number of effective perforation clusters 172 includes the control center 174 using an autoencoder to automatically compress the inputs received from the sensors 228 associated with the wellsite equipment 226 of the wellsite system 100 of FIG. 1 into a smaller number of outputs relating to operational parameters of the wellsite equipment 226 (block 234). As illustrated in FIG. 5, in certain embodiments, an autoencoder 242 may be used by the control center 174 to automatically compress the seven inputs X (i.e., X₁—Clean Fluid Rate, X₂—Total Fluid, X₃—Total Proppant, X₄—Proppant Concentration, X₅—Total Slurry, X₆—Slurry Rate, and X₇—Treatment Pressure) received from the sensors 228 associated with the wellsite equipment 226 into four outputs X′ (i.e., X′₁, X′₂, X′₃, and X′₄) relating to operational parameters of the wellsite equipment 226. The number of outputs X′ (i.e., four) has been found to be optimal insofar as it seems to be the smallest number that is still able to hold all of the information to represent downhole flow rate allocation across perforation clusters 172. In addition, it has been found that the data compression provided by the autoencoder 242 allows the model to generalize across different wells regardless of their physical location and geological setting. However, it should be noted that, in other embodiments, the autoencoder 242 may not be used to automatically compress the inputs X into the outputs X′. Rather, in certain embodiments, the seven inputs X may be used as the outputs X′ or may be otherwise converted into a smaller number of outputs X′ using techniques other than an autoencoder 242. However, in general, it has been found that using an autoencoder 242 generally leads to quicker and more accurate determination of the number of effective perforation clusters 172.

In addition, as illustrated in FIG. 4, the method 230 for determining and using a number of effective perforation clusters 172 includes the control center 174 automatically stacking the outputs X′ to generate time series of the outputs X′ to provide time histories of certain features relating to operational parameters of the wellsite equipment 226 of the wellsite system 100 of FIG. 1 (block 236). In general, the time series of the outputs X′ represent a time dependency of downhole rate distribution across the perforations of the perforation clusters 172 with respect to time. In addition, the time series of the outputs X′ are the most active representation of perforation erosion evolution during the hydraulic fracturing treatment. It has been found that an optimal number of timesteps is approximately 120, which has proved effective given the typical frequency of surface datasets. However, in other embodiments, other numbers of timesteps may be used, such as between 110 and 130, between 100 and 140, between 90 and 150, between 80 and 160, between 60 and 180, and so forth.

In addition, as illustrated in FIG. 4, the method 230 for determining and using a number of effective perforation clusters 172 includes using a convolutional neural network (CNN) 244 to automatically analyze the time series of the outputs X′ to determine a number of effective perforation clusters 172 (block 238). It has been found that the use of CNNs, rather than recurrent neural networks (RNNs), provides superior determination of the number of effective perforation clusters 172, as described herein. CNNs are a particular type of neural network that are often used in visual imaging analysis because of the way in which the neurons function similarly to visual processing performed by the human brain (i.e., the visual cortex). As opposed to RNNs, CNNs use convolution instead of matrix multiplication. Convolution is a mathematical process by which a mathematical operation (e.g., f(x)*g(x) in on example) of two or more functions (e.g., f(x) and g(x) in the example) define another function (e.g., h(x)). In the context of determining a number of effective perforation clusters 172, as described herein, the time series of the outputs X′ are analogous to images, and the stacked timesteps of the time series of the outputs X′ are analogous to pixels of images.

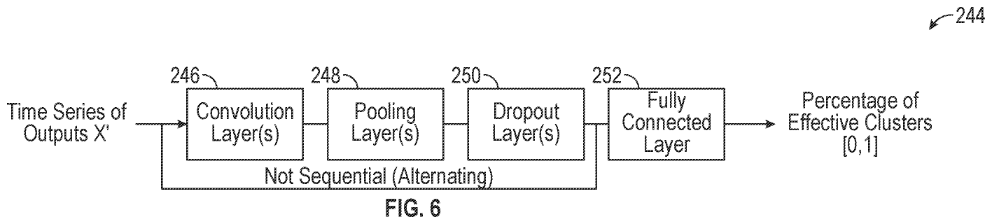

As illustrated in FIG. 6, in certain embodiments, the CNN 244 used by the control center 174 includes one or more convolution layers 246 (e.g., whereby one or more convolution filters are applied to time series of outputs X′), each associated with one or more pooling layers 248 (e.g., whereby sizes of the convolved features from the respective convolution layer 246 are reduced), one or more dropout layers 250 (e.g., whereby certain nodes in the network are dropped out), and a fully connected layer 252 (e.g., whereby nonlinear function of high-level features are learned). In certain embodiments, the control center 174 may conduct hyperparameter optimization to choose activations, kernel sizes, layers, maximum poolings, and so forth, of the CNN 244. Although illustrated in FIG. 6 for convenience as being sequential, the one or more convolution layers 246, the one or more pooling layers 248, and the one or more dropout layers 250 are not, indeed, sequential. Rather, these layers may alternate in any combination of orders, for example, depending on the hyperparameterization. For example, in certain embodiments, the layers may alternate such as convolution layer 246, pooling layer 248, dropout layer 250, convolution layer 246, dropout layer 250, and so forth.

In addition, in certain embodiments, the number of perforations (e.g., as determined from the completion design) may be added as an input to the CNN 244 alongside the four outputs X′. It has been found (e.g., from downhole fiber optic measurements) that flow allocation per perforation cluster 172 generally follows a Gaussian distribution. As such, in certain embodiments, the CNN 244 used by the control center 174 determines probability that a perforation cluster 172 is between a pre-defined percentage of mean designed flowrate per perforation cluster 172.

In addition, as illustrated in FIG. 4, the method 230 for determining and using a number of effective perforation clusters 172 includes the control center 174 (e.g., automatically, in certain embodiments) controlling operational parameters of the wellsite equipment 226 of the wellsite system 100 of FIG. 1 based at least in part on the determined number of effective perforation clusters 172 (block 240). For example, in certain embodiments, the control center 174 may (e.g., automatically, in certain embodiments) send control signals to the pumps 152, as well as to other wellsite equipment of the wellsite system 100, to (e.g., automatically, in certain embodiments) adjust operational parameters such as the clean fluid rate, the total amount of fluid used, the total amount of proppant used, the concentration of proppant used, the total amount of slurry, the slurry rate, and the treatment pressure, among other operational parameters.

As the number of perforations may be an input for the CNN model (e.g., again, available the completion design), the CNN 244 used by the control center 174 may determine the number of effective stimulated clusters that fulfill the designed flowrate within a given tolerance. In certain embodiments, machine learning reinforcement of the CNN model allows optimization of the key (e.g., seven, as described herein) input parameters X to increase the number of effective perforation clusters 172. In general, the CNN model determines optimum execution conditions. In certain embodiments, historical production datasets may be combined with the CNN model output to determine proper completion practices to optimize completion design and its application to future developments.

Accordingly, the autoencoder 242 and the CNN 244 illustrated in FIGS. 5 and 6 may collectively function together to form an autoencoder/CNN architecture configured to enable the control center 174 to determine a number of effective perforation clusters 172 based on collected surface data in substantially real-time during a hydraulic fracturing treatment, which in turn enables the control center 174 to actively (e.g., automatically) adjust operational parameters of the wellsite equipment 226 of the wellsite system 100 in substantially real-time such that the number of effective perforation clusters 172 may be actively optimized during performance of the hydraulic fracturing treatment. It will be appreciated that the time series of the outputs X′ generated by the autoencoder 242 may be converted into a particular data format suitable for the CNN 244 to analyze, as described in greater detail herein.

As described in greater detail herein, inputs to the autoencoder/CNN architecture generally include a first tensor T₁∈R^{120×7} (i.e., 120 past timestep time series of the seven inputs X described above) and a second tensor T₂∈R¹ (i.e., cluster effectiveness percentage), and the CNN model (i.e., an autoencoder feature extractor linked with a convolutional neural network) generates an output of a floating number between 0 to 1, which represents the percentage of effective perforation clusters 172.

As described in greater detail herein, the autoencoder/CNN architecture acts on real-time surface datasets, which enables real-time decision making during the execution of a stimulation job. In general, the intent of the CNN model output is to denote accuracy of a hydraulic fracturing treatment relative to the planned slurry flowrate allocated per perforation cluster design. In addition, the autoencoder/CNN architecture described herein determines the accuracy of the hydraulic fracturing treatment versus designed parameters, but allows the optimization of surface pump rate to enhance/increase the number of effective perforation clusters 172 relative to the planned cluster flowrate from the completion design. In this manner, the outputs of the autoencoder/CNN architecture described herein are actionable and allow immediate application for future completions.

The specific embodiments described above have been illustrated by way of example, and it should be understood that these embodiments may be susceptible to various modifications and alternative forms. It should be further understood that the claims are not intended to be limited to the particular forms disclosed, but rather to cover all modifications, equivalents, and alternatives falling within the spirit and scope of this disclosure.

1. A computer-implemented method, comprising:
receiving, via a control center, a plurality of inputs relating to operational parameters of wellsite equipment of a wellsite system during hydraulic fracturing operations performed for the wellsite system;
converting, via the control center, the plurality of inputs into a plurality of outputs relating to operational parameters of the wellsite equipment;
generating, via the control center, time series of the plurality of outputs;
using, via the control center, a convolutional neural network to analyze the time series of the plurality of outputs to determine a number of effective perforation clusters created during the hydraulic fracturing operations; and
controlling, via the control center, operational parameters of the wellsite equipment based at least in part on the determined number of effective perforation clusters.

2. The computer-implemented method of claim 1, wherein the plurality of inputs comprise inputs relating to a clean fluid rate, a total amount of fluid used, a total amount of proppant used, a concentration of proppant used, a total amount of slurry, a slurry rate, and a treatment pressure.

3. The computer-implemented method of claim 1, wherein the plurality of outputs comprise four outputs.

4. The computer-implemented method of claim 1, wherein the plurality of inputs are received from sensors associated with the wellsite equipment in substantially real-time during the hydraulic fracturing operations.

5. The computer-implemented method of claim 1, wherein converting the plurality of inputs into a plurality of outputs comprises using an autoencoder to compress the plurality of inputs into a smaller number of outputs.

6. The computer-implemented method of claim 1, wherein generating the time series of the plurality of outputs comprises stacking the plurality of outputs with approximately 120 timesteps.

7. The computer-implemented method of claim 1, wherein the convolutional neural network uses a number of perforation clusters created during the hydraulic fracturing operations to determine the number of effective perforation clusters.

8. The computer-implemented method of claim 1, wherein controlling the operational parameters of the wellsite equipment comprises controlling the operational parameters of the wellsite equipment in substantially real-time.

9. A system, comprising:
a control center configured to control operational parameters of wellsite equipment of a wellsite system during hydraulic fracturing operations performed for the wellsite system, wherein the control center is configured to control the operational parameters of the wellsite equipment based at least in part on a number of effective perforation clusters created during the hydraulic fracturing operations, wherein the control center comprises:
an autoencoder configured to receive a plurality of inputs relating to operational parameters of the wellsite equipment, and to compress the plurality of inputs into a plurality of outputs, wherein a number of the plurality of outputs is less than a number of the plurality of inputs; and
a convolutional neural network configured to analyze time series of the plurality of outputs to determine the number of effective perforation clusters.

10. The system of claim 9, wherein the plurality of inputs comprise inputs relating to a clean fluid rate, a total amount of fluid used, a total amount of proppant used, a concentration of proppant used, a total amount of slurry, a slurry rate, and a treatment pressure.

11. The system of claim 9, wherein the plurality of outputs comprise four outputs.

12. The system of claim 9, wherein the plurality of inputs are received from sensors associated with the wellsite equipment in substantially real-time during the hydraulic fracturing operations.

13. The system of claim 9, wherein the time series of the plurality of outputs comprise 120 timesteps.

14. The system of claim 9, wherein the convolutional neural network uses a number of perforation clusters created during the hydraulic fracturing operations to determine the number of effective perforation clusters.

15. The system of claim 9, wherein controlling the operational parameters of the wellsite equipment comprises controlling the operational parameters of the wellsite equipment in substantially real-time.

16. A tangible, non-transitory machine-readable medium, comprising processor-executable instructions that, when executed by at least one processor, cause the at least one processor to:
receive a plurality of inputs relating to operational parameters of wellsite equipment of a wellsite system during hydraulic fracturing operations performed for the wellsite system;
use an autoencoder to compress the plurality of inputs into a plurality of outputs, wherein a number of the plurality of outputs is less than a number of the plurality of inputs;
generate time series of the plurality of outputs;
use a convolutional neural network to analyze the time series of the plurality of outputs to determine a number of effective perforation clusters created during the hydraulic fracturing operations; and
control operational parameters of the wellsite equipment based at least in part on the determined number of effective perforation clusters.

17. The tangible, non-transitory machine-readable medium of claim 16, wherein the plurality of inputs comprise inputs relating to a clean fluid rate, a total amount of fluid used, a total amount of proppant used, a concentration of proppant used, a total amount of slurry, a slurry rate, and a treatment pressure.

18. The tangible, non-transitory machine-readable medium of claim 16, wherein the plurality of outputs comprise four outputs.

19. The tangible, non-transitory machine-readable medium of claim 16, wherein the plurality of inputs are received from sensors associated with the wellsite equipment in substantially real-time during the hydraulic fracturing operations.

20. The tangible, non-transitory machine-readable medium of claim 16, wherein the time series of the plurality of outputs comprise 120 timesteps.

21. The tangible, non-transitory machine-readable medium of claim 16, wherein the processor-executable instructions, when executed by the at least one processor, cause the at least one processor to use a number of perforation clusters created during the hydraulic fracturing operations to determine the number of effective perforation clusters.

22. The tangible, non-transitory machine-readable medium of claim 16, wherein the processor-executable instructions, when executed by the at least one processor, cause the at least one processor to control the operational parameters of the wellsite equipment in substantially real-time.
